(19) United States
(12) Patent Application Publication
(10) Pub. No.: US 2025/0194248 A1
(43) Pub. Date: Jun. 12, 2025

(54) DRIVING SUBSTRATE, MANUFACTURING METHOD THEREOF AND DISPLAY PANEL

(71) Applicant: TCL CHINA STAR OPTOELECTRONICS TECHNOLOGY CO., LTD., Shenzhen (CN)

(72) Inventor: Jinming LI, Shenzhen (CN)

(73) Assignee: TCL CHINA STAR OPTOELECTRONICS TECHNOLOGY CO., LTD., Shenzhen (CN)

(21) Appl. No.: 18/399,492

(22) Filed: Dec. 28, 2023

(30) Foreign Application Priority Data
Dec. 8, 2023 (CN) 202311693300.8

(51) Int. Cl. H01L 27/12

(52) U.S. Cl. CPC H10D 86/60; H10D 86/0221; H10D 86/421; H10D 86/471

(57) ABSTRACT

A driving substrate, a manufacturing method thereof and a display panel are provided. First thin film transistors are provided in a pixel region and second thin film transistors are provided in a frame region, in which a first active layer of the first thin film transistor includes an amorphous silicon layer and a microcrystalline silicon layer stacked, and a channel of the second active layer of the second thin film transistor includes polysilicon, so that mobility of the second thin film transistor is greater than that of the first thin film transistor. Also, the polysilicon can be formed by crystallizing the amorphous silicon layer and the microcrystalline silicon layer, which are stacked, as a monolithic crystal.

### CROSS-REFERENCE TO RELATED APPLICATION

This application claims priority to and the benefit of Chinese Patent Application No. 202311693300.8, filed on Dec. 8, 2023, the disclosure of which is incorporated herein by reference in its entirety.

### TECHNICAL FIELD

The present application relates to the field of display technology, and more particularly, to a driving substrate, a manufacturing method thereof, and a display panel.

### BACKGROUND

In the array substrate made by using the amorphous silicon (a-Si) process in the related art, the inward (pixel region) thin film transistors each need to have a lower mobility than that of the outward (frame region) thin film transistors, and the use of uniform amorphous silicon as channels of the thin film transistors results in insufficient mobility of the outward thin film transistors.

For example, in a demultiplexing (De-mux) circuitry, the time division multiplexing is performed when a data signal input needs to be satisfied, so that pins of source driving chips are reduced, and the number of driving chips is reduced. Therefore, mobility of thin film transistors in the De-mux circuitry are required to be larger. In order to meet the above-mentioned needs, it is conventional to replace the outward thin film transistors formed by a-Si process with the thin film transistor formed by IGZO process, but the cost of this method is large and the fabrication process of the entire array substrate is more cumbersome.

### SUMMARY

According to embodiments of the present application, it is provided a driving substrate, a manufacturing method thereof, and a display panel, which can improve the mobility of second thin film transistors located in a frame region while reducing costs.

According to embodiments of the present disclosure, it is provided a driving substrate including a pixel region and a frame region, the frame region being located on at least one side of the pixel region, the driving substrate including: a base; first thin film transistors disposed on the base and located in the pixel region, wherein each of the first thin film transistors comprises a first active layer, and the first active layer comprises a first amorphous silicon layer and a first microcrystalline silicon layer disposed on a side of the first amorphous silicon layer which is away from the base; and second thin film transistors disposed on the base and located in the frame region, wherein each of the second thin film transistors comprises a second active layer, the second active layer comprises a second channel comprising polysilicon, and electron mobility of the second thin film transistor is greater than electron mobility of the first thin film transistor.

Optionally, in some embodiments of the present application, the first active layer comprises a first source contact portion, a first drain contact portion, and a first channel, the first source contact portion is connected to one side of the first channel, the first drain contact portion is connected to an other side of the first channel, wherein the first source contact portion, the first drain contact portion, and the first channel each comprise the first amorphous silicon layer and the first microcrystalline silicon layer stacked; the second active layer comprises a second source contact portion and a second drain contact portion, the second source contact portion is connected to one side of the second channel, the second drain contact portion is connected to an other side of the second channel, and the second source contact portion and the second drain contact portion are each made of the polysilicon.

Optionally, in some embodiments of the present application, the first active layer further comprises a first source contact portion, a first drain contact portion, and a first channel, the first source contact portion is connected to one side of the first channel, the first drain contact portion is connected to an other side of the first channel, wherein the first source contact portion, the first drain contact portion, and the first channel each comprise the first amorphous silicon layer and the first microcrystalline silicon layer stacked; the second active layer further comprises a second source contact portion and a second drain contact portion, the second source contact portion is connected to one side of the second channel, the second drain contact portion is connected to an other side of the second channel, the second source contact portion comprises a second amorphous silicon layer and a second microcrystalline silicon layer, the second microcrystalline silicon layer is disposed on a side of the second amorphous silicon layer which is away from the base, the second drain contact portion comprises a third amorphous silicon layer and a third microcrystalline silicon layer, and the third microcrystalline silicon layer is disposed on a side of the third amorphous silicon layer which is away from the base.

Optionally, in some embodiments of the present application, the polysilicon is formed by crystallizing a fourth amorphous silicon layer and a fourth microcrystalline silicon layer, which are stacked, as a monolithic crystal, the fourth amorphous silicon layer is provided in a same layer as the first amorphous silicon layer, and the fourth microcrystalline silicon layer is provided in a same layer as the first microcrystalline silicon layer.

Optionally, in some embodiments of the present application, the polysilicon has a grain width greater than 2 microns.

Optionally, in some embodiments of the present application, the polysilicon has a grain width greater than 6 microns.

Optionally, in some embodiments of the present application, a thickness of the first microcrystalline silicon layer is between 10% and 30% of a thickness of the first active layer.

Optionally, in some embodiments of the present application, the driving substrate further comprises a gate insulating layer, the first thin film transistor comprises a first gate, the second thin film transistor comprises a second gate, the first gate and the second gate are both disposed on the base, the gate insulating layer covers the first gate and the second gate, the first active layer is disposed on a side of the gate insulating layer which is away from the base, and the second active layer is disposed on a side of the gate insulating layer which is away from the base; in an orthographic projection pattern of the driving substrate, the first active layer and the first gate are overlapped, and the second active layer and the second gate are overlapped; the gate insulating layer comprises a silicon oxide layer and a silicon nitride layer, the silicon nitride layer is disposed on a side of the silicon oxide layer which is away from the base.

Optionally, in some embodiments of the present application, a thickness of the silicon nitride layer is greater than a thickness of the silicon oxide layer.

Optionally, in some embodiments of the present application, a thickness of the silicon oxide layer is less than or equal to 250 nm, and a thickness of the silicon nitride layer is between 200 nm and 400 nm.

Optionally, in some embodiments of the present application, the first thin film transistor further comprises a first ohmic contact layer, a first source and a first drain, and the second thin film transistor further comprises a second ohmic contact layer, a second source and a second drain; a portion of the first ohmic contact layer is provided on the first source contact portion, an other portion of the first ohmic contact layer is provided on the first drain contact portion, the first source is connected to the first source contact portion through the portion of the first ohmic contact layer, and the first drain is connected to the first drain contact portion through the other portion of the first ohmic contact layer; a portion of the second ohmic contact layer is provided on the second source contact portion, an other portion of the second ohmic contact layer is provided on the second drain contact portion, the second source is connected to the second source contact portion through the portion of the second ohmic contact layer, and the second drain is connected to the second drain contact portion through the other portion of the second ohmic contact layer.

Optionally, in some embodiments of the present application, the driving substrate comprises a demultiplexing circuitry, the demultiplexing circuitry comprises ones of the second thin film transistors, a gate of each of the ones of the second thin film transistors is connected to a corresponding one of signal control terminals, first electrodes of the ones of the second thin film transistors are connected to a data signal input terminal, and a second electrode of each of the ones of the second thin film transistors is connected to a corresponding one of data lines.

According to embodiments of the present application, it is further provided a display panel including the driving substrate according to any one of the above embodiments.

According to embodiments of the present application, it is further provided a manufacturing method of a driving substrate, including: forming first gates and second gates on a base, wherein each of the first gates is located in a pixel region and each of the second gates is located in a frame region; forming a gate insulating layer on the base, wherein the gate insulating layer covers the first gates and the second gates; sequentially forming an amorphous silicon material layer and a microcrystalline silicon material layer on the gate insulating layer, patterning the amorphous silicon material layer and the microcrystalline silicon material layer to form a first active layer located in the pixel region and a second active layer located in the frame region, wherein the first active layer comprises a first source contact portion, a first drain contact portion, and a first channel, the first source contact portion is connected to one side of the first channel, the first drain contact portion is connected to an other side of the first channel, and the first source contact portion, the first drain contact portion, and the first channel each comprises a first amorphous silicon layer and a first microcrystalline silicon layer stacked; dehydrogenating and crystallizing at least a portion of the second active layer to form polysilicon, wherein the second active layer comprises a second source contact portion, a second drain contact portion, and a second channel, the second source contact portion is connected to one side of the second channel, the second drain contact portion is connected to an other side of the second channel, and the second channel are made of the polysilicon; sequentially forming an ohmic contact material layer and a source-drain metal layer on one side of both the first active layer and the second active layer which is away from the base, and patterning the ohmic contact material layer and the source-drain metal layer to form first sources, first drains, a first ohmic contact layer, a second ohmic contact layer, second sources and second drains, wherein each of the first gates, the first active layer, the first ohmic contact layer, a respective one of the first sources and a respective one of the first drains form a first thin film transistor, and each of the second gates, the second active layer, the second ohmic contact layer, a respective one of the second sources and a respective one of the second drains form a second thin film transistor; the first source is connected to the first source contact portion through a portion of the first ohmic contact layer, the first drain is connected to the first drain contact portion through an other portion of the first ohmic contact layer, the second source is connected to the second source contact portion through a portion of the second ohmic contact layer, and the second drain is connected to the second drain contact portion through an other portion of the second ohmic contact layer.

In the driving substrate according to embodiments of the present application, first thin film transistors are provided in a pixel region and second thin film transistors are provided in a frame region, in which a first active layer of the first thin film transistor includes an amorphous silicon layer and a microcrystalline silicon layer stacked, and a channel of the second active layer of the second thin film transistor includes polysilicon, so that mobility of the second thin film transistor is greater than that of the first thin film transistor. Also, since the polysilicon can be formed by crystallizing the amorphous silicon layer and the microcrystalline silicon layer, which are stacked, as a monolithic crystal, the process is simplified, so that the mobility of the second thin film transistor located in the frame region can be improved while the cost is reduced.

### BRIEF DESCRIPTION OF THE DRAWINGS

FIG. 1 is a schematic structural diagram of a driving substrate according to embodiments of the present application;

FIG. 2 is another schematic structural diagram of a driving substrate according to embodiments of the present application;

FIG. 3 is yet another schematic structural diagram of a driving substrate according to embodiments of the present application;

FIG. 4 is a driving circuitry diagram of a driving substrate according to embodiments of the present application;

FIG. 5 is a schematic diagram of a step of a manufacturing method of a driving substrate according to embodiments of the present application;

FIG. 6 is another schematic diagram of a step of a manufacturing method of a driving substrate according to embodiments of the present application;

FIG. 7 is yet another schematic diagram of a step of a manufacturing method of a driving substrate according to embodiments of the present application;

FIG. 8 is yet another schematic diagram of a step of a manufacturing method of a driving substrate according to embodiments of the present application;

FIG. 9 is yet another schematic diagram of a step of a manufacturing method of a driving substrate according to embodiments of the present application;

FIG. 10 is yet another schematic diagram of a step of a manufacturing method of a driving substrate according to embodiments of the present application; and

FIG. 11 is a flowchart of a manufacturing method of a driving substrate according to embodiments of the present application.

### DETAILED DESCRIPTION

In the following, the technical solutions in the embodiments of the present application will be clearly and completely described in connection with the accompanying drawings in the embodiments of the present application. It will be apparent that the described embodiments are merely a part of the embodiments of the present application, rather than all the embodiments. Based on the embodiments in the present application, all other embodiments obtained by a person skilled in the art without involving any inventive effort are within the scope of the present application. Furthermore, it is to be understood that the specific embodiments described herein are for purposes of illustration and explanation only and are not intended to limit the application. In the present disclosure, without any explanation to the contrary, directional terms used herein such as “upper” and “lower” usually refer to the upper and lower positions of a device in an actual use or working state, specifically the direction of the figures of the accompanying drawings, and terms “inner” and “outer” refer to a profile of the device. The terms “first,” “second,” “third,” and the like are used merely as labels and do not impose numerical requirements or order of establishment.

According to embodiments of the present application, it is provided a driving substrate, a manufacturing method thereof, and a display panel, which are described in detail below. It should be noted that the order in which the following examples are described is not intended to limit the preferred order of the examples.

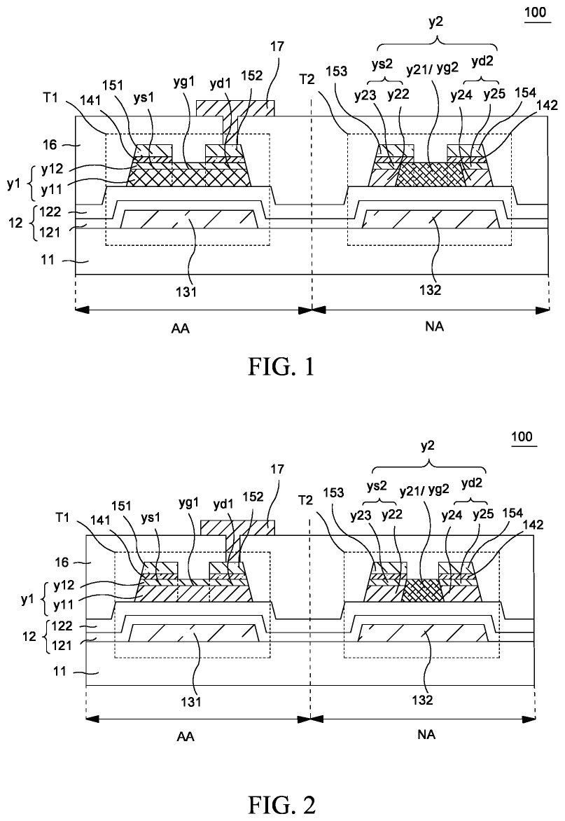

As shown in FIG. 1, according to embodiments of the present application, it is provided a driving substrate 100 including a pixel region AA and a frame region NA. The frame region NA is located on at least one side of the pixel region AA. The driving substrate 100 includes a base 11, a first thin film transistor T1, and a second thin film transistor T2.

The first thin film transistor T1 is provided on the base 11 and is located in the pixel region AA. The first thin film transistor T1 includes a first active layer y1 including a first amorphous silicon layer y11 and a first microcrystalline silicon layer y12. The first microcrystalline silicon layer y12 is disposed on a side of the first amorphous silicon layer y11 which is away from the base 11.

The second thin film transistor T2 is provided on the base 11 and is located in the frame region NA. The second thin film transistor T2 includes a second active layer y2, and a channel of the second active layer y2 includes polysilicon. The electron mobility of the second thin film transistor T2 is greater than the electron mobility of the first thin film transistor T1.

In the driving substrate 100 according to embodiments of the present application, first thin film transistors T1 are provided in a pixel region AA and second thin film transistors T2 are provided in a frame region NA, in which a first active layer y1 of the first thin film transistors T1 includes an amorphous silicon layer y11 and a microcrystalline silicon layer y12 stacked, and a channel of the second active layer y2 of the second thin film transistor T2 includes polysilicon, so that the mobility of the second thin film transistor T2 is greater than that of the first thin film transistor T1. Also, since the polysilicon can be formed by crystallizing the amorphous silicon layer and the microcrystalline silicon layer, which are stacked, as a monolithic crystal, the process is simplified, so that the mobility of the second thin film transistor T2 located in the frame region NA can be improved while the cost is reduced in the present application.

Optionally, the first microcrystalline silicon layer y12 is directly disposed on the first amorphous silicon layer y11.

Optionally, each of the first thin film transistor T1 and the second thin film transistor T2 may be a thin film transistor such as a top gate type, a bottom gate type, or a double gate type. In the present application, the first thin film transistor T1 and the second thin film transistor T2 are both bottom gate thin film transistors, for example, but not limited thereto.

Optionally, the first active layer y1 further includes a first source contact portion ys1, a first drain contact portion yd1 and a first channel yg1. The first source contact portion ys1 is connected to one side of the first channel yg1, the first drain contact portion yd1 is connected to the other side of the first channel yg1. The first source contact portion ys1, the first drain contact portion yd1, and the first channel yg1 each include a first amorphous silicon layer y11 and a first microcrystalline silicon layer y12 that are stacked.

The second active layer y2 further includes a second source contact portion ys2, a second drain contact portion yd2, and a second channel yg2. The second source contact portion ys2 is connected to one side of the second channel yg2, and the second drain contact portion yd2 is connected to the other side of the second channel yg2. The second channel yg2 is polysilicon.

The second channel yg2 of the second thin film transistor T2 is polysilicon and has higher electron mobility, compared with the first channel yg1 of the first thin film transistor T1 being an amorphous silicon layer and a microcrystalline silicon layer that are stacked.

In the present embodiment, the second source contact portion ys2 includes a second amorphous silicon layer y22 and a second microcrystalline silicon layer y23. The second microcrystalline silicon layer y23 is disposed on a surface of the second amorphous silicon layer y22 which is away from the base 11. The second drain contact portion yd2 includes a third amorphous silicon layer y24 and a third microcrystalline silicon layer y25. The third microcrystalline silicon layer y25 is disposed on a surface of the third amorphous silicon layer y24 which is away from the base 11.

The second channel yg2 is polysilicon, that is, the second channel yg2 is a single layer of polysilicon layer y21. The polysilicon layer y21 also extends from the channel region of the second active layer y2 and is provided in the source contact region and the drain contact region of the second active layer y2. So, the second source contact portion ys2 also includes a portion of the polysilicon layer y21, and the second drain contact portion yd2 also includes a portion of the polysilicon layer y21.

That is, in the present embodiments, the amorphous silicon layer and the microcrystalline silicon layer that are stacked are partially crystallized as a whole in a manner of partial crystallization, thereby reducing the process cost and providing process efficiency compared with the unitary crystallization. The polysilicon layer y21 is partially located in the source contact region and the drain contact region, which can improve the conductivity of the second source contact portion ys2 and the second drain contact portion yd2.

It will be appreciated that the polysilicon layer (polysilicon) y21 is formed from an amorphous silicon layer and a microcrystalline silicon layer, which are stacked, as a monolithic crystal. The amorphous silicon layer is disposed in the same layer as the first amorphous silicon layer y11, and the microcrystalline silicon layer is disposed in the same layer as the first microcrystalline silicon layer y12. Since the polysilicon in the second active layer y2 is formed by crystallizing the same material as the first active layer y1 of the pixel region AA, the additional semiconductor material with high mobility is not required, and process costs can be reduced.

In addition, compared with using amorphous silicon to crystallize to form polycrystalline silicon, an amorphous silicon layer and a microcrystalline silicon layer stacked are used to crystallize to form polycrystalline silicon. In this way, since the microcrystalline silicon layer is already a crystalline silicon layer, when the microcrystalline silicon layer is converted to polycrystalline silicon layer, the microcrystalline silicon layer can act as a seed to induce rapid crystallization of the amorphous silicon. At the same thickness, the crystallization energy required for crystallizing and forming polycrystalline silicon by using the amorphous silicon layer and the microcrystalline silicon layer stacked is greatly reduced, for example, by more than 30%, which can greatly reduce energy consumption and further reduce cost.

Alternatively, the electron mobility of the second thin film transistor T2 is greater than or equal to 150 cm²/Vs, and may be, for example, 155 cm²/Vs, 160 cm²/Vs, 165 cm²/Vs, 170 cm²/Vs, 175 cm²/Vs, 180 cm²/Vs, 185 cm²/Vs, 190 cm²/Vs, 195 cm²/Vs, or 200 cm²/Vs.

Referring to FIG. 2, in some embodiments, the polysilicon layer y21 is located only in the channel region of the second thin film transistor T2.

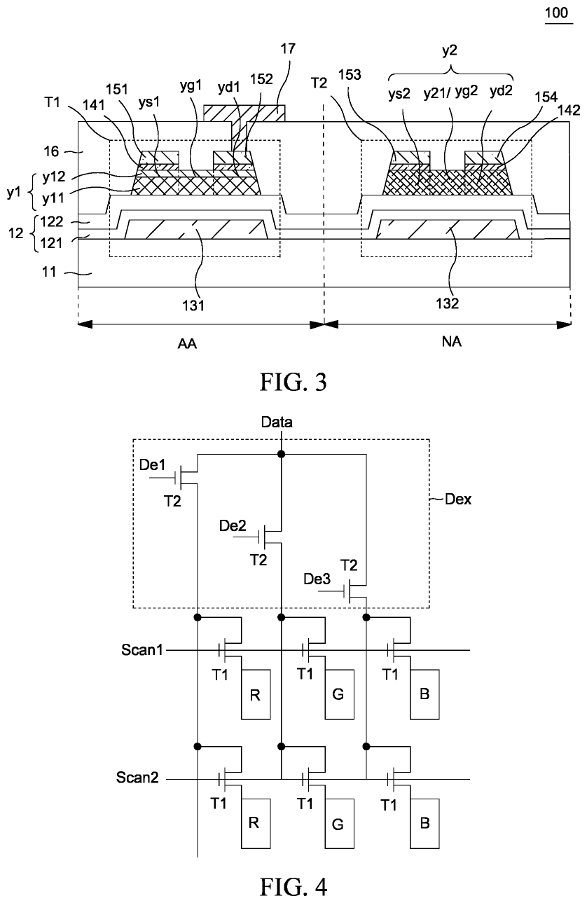

Referring to FIG. 3, in some embodiments, the materials of the second source contact portion ys2, the second drain contact portion yd2, and the second channel yg2 are all polysilicon, that is, the entire second active layer y2 is a polysilicon layer y21. Here, the entire second active layer y2 is subjected to a crystallization process, and the second active layer y2 can be subjected to a regional laser scanning crystallization process, thereby improving the processing efficiency and further improving the conductive performance of the second source contact portion ys2 and the second drain contact portion yd2.

Alternatively, the polysilicon layer y21 has a grain width greater than 2 microns. For example, the grain width of the polysilicon layer y21 may be 2.1 microns, 2.2 microns, 2.3 microns, 2.5 microns, 3 microns, 4 microns, 5 microns, 6 microns, 7 microns, or the like.

It will be appreciated that, at the same channel width, the larger the grain width of the polysilicon layer y21 and the smaller the grain boundary, the higher the mobility of the channel.

Alternatively, the polysilicon layer y21 has a grain width greater than 6 microns. When a Blue Laser Diode Annealing (BLDA) process is used, the crystal width of the polysilicon layer y21 may be greater than or equal to 6 microns, further improving the mobility of the channel. For example, the grain width of the polysilicon layer y21 may be 6 microns, 6.1 microns, 6.2 microns, 6.3 microns, 6.4 microns, 6.5 microns, 6.6 microns, 6.7 microns, 6.8 microns, 6.9 microns, 7 microns, 7.5 microns, 8 microns, or the like.

Optionally, a thickness of the first microcrystalline silicon layer y12 is between 10% and 30% of a thickness of the first active layer y1.

Here, when the thickness proportion of the first microcrystalline silicon layer y12 is larger, the mobility of the first active layer y1 is higher, and the film forming time of the first active layer y1 is longer. However, when the thickness of the first microcrystalline silicon layer y12 reaches a certain level, the efficiency of increasing the mobility of the first active layer y1 is lower and lower. Therefore, the thickness of the first microcrystalline silicon layer y12 is set to be 10% to 30% of the thickness of the first active layer y1, so that the efficiency of the mobility and the film forming time of the first active layer y1 is maximized.

Alternatively, the thickness of the first microcrystalline silicon layer y12 may be between 10 nanometer (nm) and 30 nm, such as 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, or 30 nm.

Alternatively, the thickness of the first active layer y1 is between 90 nm and 120 nm, such as 90 nm, 95 nm, 100 nm, 105 nm, 110 nm, 115 nm or 120 nm.

Alternatively, the driving substrate 100 further includes a gate insulating layer 12. The first thin film transistor T1 includes a first gate 131. The second thin film transistor T2 includes a second gate 132. The first gate 131 and the second gate 132 are both disposed on the base 11. The gate insulating layer 12 covers the first gate 131 and the second gate 132. A first active layer y1 is provided on one side of the gate insulating layer 12 which is away from the base 11. The second active layer y2 is provided on one side of the gate insulating layer 12 which is away from the base 11.

In the orthographic projection pattern of the driving substrate 100, the first active layer y1 and the first gate 131 are provided in an overlapping manner. The second active layer y2 is overlapped with the second gate 132.

The gate insulating layer 12 includes a silicon oxide layer 121 and a silicon nitride layer 122. The silicon nitride layer 122 is provided on a surface of the silicon oxide layer 121 which is away from the base 11.

It will be appreciated that the thickness of the gate insulating layer 12 may affect the threshold voltage of the thin film transistor. In the manufacturing process of the active layer, an amorphous silicon material layer is superimposed with a microcrystalline silicon material layer to perform the deposition on the whole surface, then the amorphous silicon material layer and the microcrystalline silicon material layer are patterned, and the above superimposed layer (i.e., the amorphous silicon material layer and the microcrystalline silicon material layer) is partially crystallized in the frame region NA to form polysilicon.

That is, a bottom layer of the channel of the first active layer y1 in the pixel region AA is the first amorphous silicon layer y11, and the channel of the second active layer y2 in the frame region NA is polysilicon.

Since the interface defects of amorphous silicon cannot match silicon oxide in the amorphous silicon process, the silicon nitride layer 122 provides a stable interface for the first amorphous silicon layer y11, so that the stability of the first active layer y1 is improved.

In addition, when the thin film transistor whose channel is amorphous silicon is turned on, electrons in the amorphous silicon migrate downward and combine with defects of silicon oxide, thereby increasing holes in the amorphous silicon and causing the threshold voltage to drift to the right.

Thus, the thickness of the silicon nitride layer 122 is set to be greater than the thickness of the silicon oxide layer 121, so as to reduce the risk that the threshold voltage of the first thin film transistor T1 drifts to the right.

Alternatively, the thickness of the silicon oxide layer 121 is less than or equal to 250 nm. For example, the thickness of the silicon oxide layer 121 may be 250 nm, 240 nm, 230 nm, 220 nm, 210 nm, 200 nm, 190 nm, 180 nm, 170 nm, 160 nm, 150 nm, 140 nm, or the like.

The thickness of the silicon oxide layer 121 is less than or equal to 250 nm to reduce the risk of bonding electrons in amorphous silicon to the silicon oxide layer 121, thereby reducing the risk that the threshold voltage of the first thin film transistor T1 drifts to the right.

The thickness of the silicon nitride layer 122 is between 200 nm and 400 nm. For example, the thickness of the silicon nitride layer 122 may be 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, or 400 nm.

In addition, in the case of the same thickness and the same area, the hydrogen content of the silicon nitride layer 122 is much larger than that of the silicon oxide layer 121. When the second active layer y2 of the frame region NA is dehydrogenated, the silicon nitride layer 122 also releases hydrogen. If the silicon nitride layer 122 is thicker, the hydrogen content thereof is higher, and thus the risk of hydrogen explosion is higher in the dehydrogenation process.

Therefore, the thickness of the silicon nitride layer 122 is between 200 nm and 400 nm, which reduces the risk that the threshold voltage of the first thin film transistor T1 drifts to the right, and also reduces the risk of hydrogen explosion in the dehydrogenation treatment of the second active layer y2.

Alternatively, the first thin film transistor T1 further includes a first ohmic contact layer 141, a first source 151, and a first drain 152. The second thin film transistor T2 further includes a second ohmic contact layer 142, a second source 153, and a second drain 154.

A portion of the first ohmic contact layer 141 is provided on the first source contact portion ys1, an other portion of the first ohmic contact layer 141 is provided on the first drain contact portion yd1, the first source 151 is connected to the first source contact portion ys1 through the portion of the first ohmic contact layer 141, and the first drain 152 is connected to the first drain contact portion yd1 through the other portion of the first ohmic contact layer 141.

A portion of the second ohmic contact layer 142 is provided on the second source contact portion ys2, an other portion of the second ohmic contact layer 142 is provided on the second drain contact portion yd2, the second source 153 is connected to the second source contact portion ys2 through the portion of the second ohmic contact layer 142, and the second drain 154 is connected to the second drain contact portion yd2 through the other portion of the second ohmic contact layer 142.

Alternatively, the driving substrate 100 may further include a protective layer 16 covering the first thin film transistor T1 and the second thin film transistor T2, and an electrode 17 connected to the first drain contact portion yd1 of the first thin film transistor T1 through a via hole.

Alternatively, the driving substrate 100 may be an array substrate for the liquid crystal display or a driving backplane for the electroluminescent display.

Alternatively, as shown in FIG. 4, the driving substrate 100 is an array substrate, and the second thin film transistor T2 serves as a switching device of a De-mux circuitry Dex of the driving substrate 100.

The driving substrate 100 includes the De-mux circuitry Dex. The De-mux circuitry Dex includes multiple second thin film transistors T2. A gate of each second thin film transistor T2 is connected to a corresponding signal control terminal, the first electrodes of the second thin film transistors T2 are connected to a data signal input terminal, and the second electrode of each second thin film transistor T2 is connected to a corresponding data line. The data line is correspondingly connected to multiple first thin film transistors T1.

The De-mux circuitry Dex includes three second thin film transistors T2 having respective first electrodes connected to the data signal input terminal Data. The gate of the first second thin film transistor T2 is connected to the first control signal terminal De1, the second electrode of the first second thin film transistor T2 is connected to the first electrode of the first thin film transistor T1, and the second electrode of the first thin film transistor T1 is connected to an electrode 17 (corresponding to the red pixel R).

The gate of the second second thin film transistor T2 is connected to the second control signal terminal De2, the second electrode of the second second thin film transistor T2 is connected to the first electrode of the other first thin film transistor T1, and the second electrode of the other first thin film transistor T1 is connected to the other electrode 17 (corresponding to the green pixel G).

The gate of the third second thin film transistor T2 is connected to the third control signal terminal De3, the second electrode of the third second thin film transistor T2 is connected to the first electrode of the further first thin film transistor T1, and the second electrode of the further first thin film transistor T1 is connected to the further electrode 17 (corresponding to the blue pixel B).

The gates of the first thin film transistors T1 in the first row are connected to a scan signal terminal Scan1. The gates of the first thin film transistors T1 in the second row are connected to a scan signal terminal Scan2.

By the arrangement of the De-mux circuitry Dex, the number of the data signal input terminals data can be reduced, thereby reducing the number of the source driver chips.

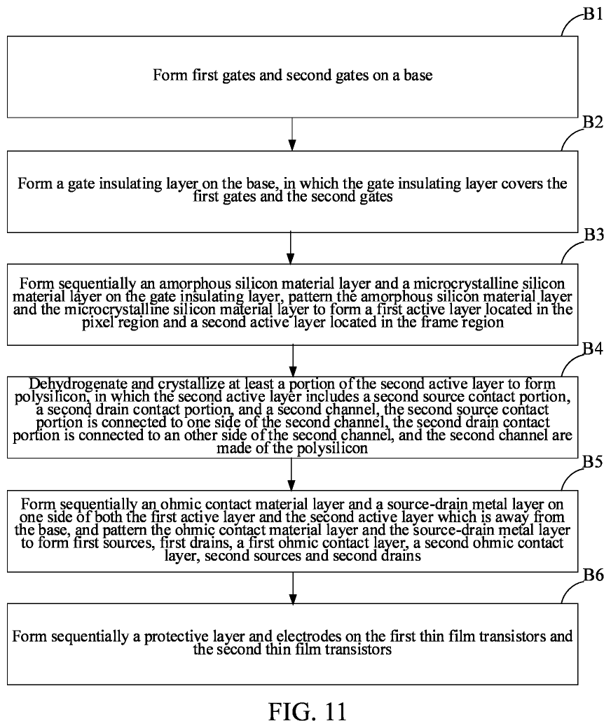

Accordingly, according to embodiments of the present application, it is further provided a manufacturing method of a driving substrate, including steps B1 to B6, as shown in FIG. 11.

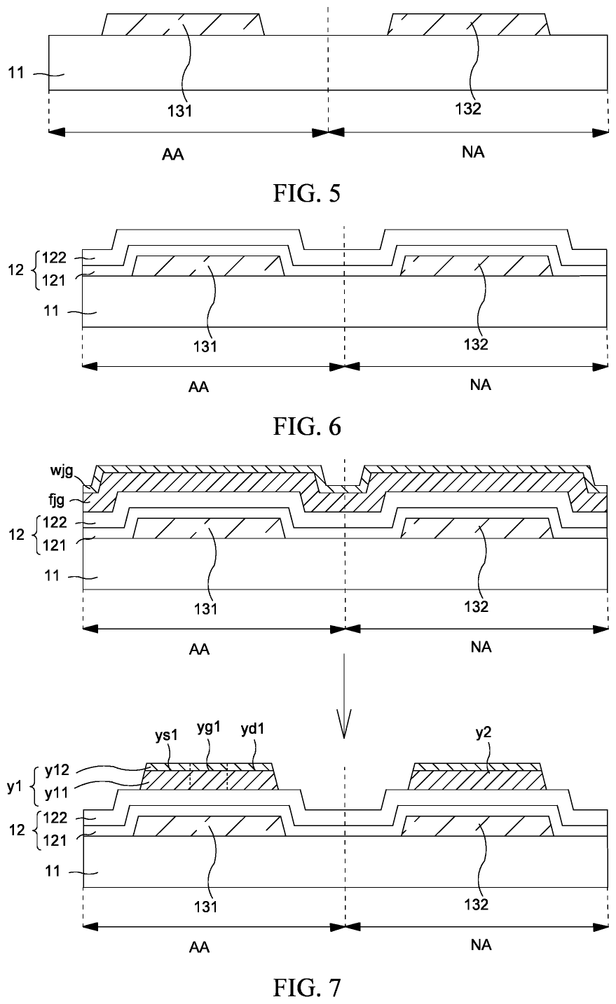

At step B1, with further reference to FIG. 5, first gates 131 and second gates 132 are formed on the base 11. The first gates 131 are located in the pixel region AA, and the second gates 132 are located in the frame region NA. The frame area NA is located on at least one side of the pixel area AA.

Alternatively, the base 11 may be a hard substrate or a flexible substrate. Materials of the base 11 include one of glass, sapphire, silicon, silicon dioxide, polyethylene, polypropylene, polystyrene, polylactic acid, polyethylene naphthalate, polyethylene terephthalate, polyethylene naphthalate two formic acid glycol ester, polycarbonate, polyethylene, aromatic fluorotoluene containing polyarylate, polycyclic olefin, pyralene, or polyurethane.

The first gates 131 and the second gates 132 are formed by the same yellow light process and have the same material. The first gate 131 and the second gate 132 may be formed by using a metal element selected from the group consisting of chromium, copper, aluminum, gold, silver, zinc, molybdenum, tantalum, titanium, tungsten, manganese, nickel, iron, cobalt, an alloy composed of any of the metal elements described above, an alloy combining any of the metal elements described above, and the like. In addition, the first gate 131 and the second gate 132 may have a single-layer structure or a stacked structure of two or more layers.

The thickness of the first gate 131 and the second gate 132 is between 2000 Angstroms and 6000 Angstroms, and may be, for example, 2000 Angstroms, 2500 Angstroms, 3000 Angstroms, 3500 Angstroms, 4000 Angstroms, 4500 Angstroms, 5000 Angstroms, 5500 Angstroms, or 6000 Angstroms.

At step B2, with further reference to FIG. 6, a gate insulating layer 12 is formed on the base 11, in which the gate insulating layer 12 covers the first gates 131 and the second gates 132.

That is, the silicon oxide layer 121 and the silicon nitride layer 122 may be sequentially formed on the base 11 by a chemical vapor deposition process.

Alternatively, the thickness of the silicon oxide layer 121 is less than or equal to 250 nm. The thickness of the silicon nitride layer 122 is between 200 nm and 400 nm.

At step B3, with further reference to FIG. 7, an amorphous silicon material layer fjg and a microcrystalline silicon material layer wjg are sequentially formed on the gate insulating layer, the amorphous silicon material layer fjg and the microcrystalline silicon material layer wjg are patterned to form a first active layer located in the pixel region and a second active layer located in the frame region, in which the first active layer y1 includes a first source contact portion ys1, a first drain contact portion yd1, and a first channel yg1, the first source contact portion ys1 is connected to one side of the first channel yg1, the first drain contact portion yd1 is connected to an other side of the first channel yg1, and the first source contact portion ys1, the first drain contact portion yd1, and the first channel yg1 each includes a first amorphous silicon layer y11 and a first microcrystalline silicon layer y12 stacked.

Alternatively, the thickness of the microcrystalline silicon material layer wjg may be between 10 nm and 30 nm, such as 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, or 30 nm.

Alternatively, a sum of the thicknesses of the microcrystalline silicon material layer wjg and the amorphous silicon material layer fjg is between 90 nm and 120 nm, such as 90 nm, 95 nm, 100 nm, 105 nm, 110 nm, 115 nm or 120 nm.

Alternatively, the sum of the thicknesses of the microcrystalline silicon material layer wjg and the amorphous silicon material layer fjg is 100 nm. In this way, the benefits of the mobility and the film formation time of the first active layer y1 are maximized.

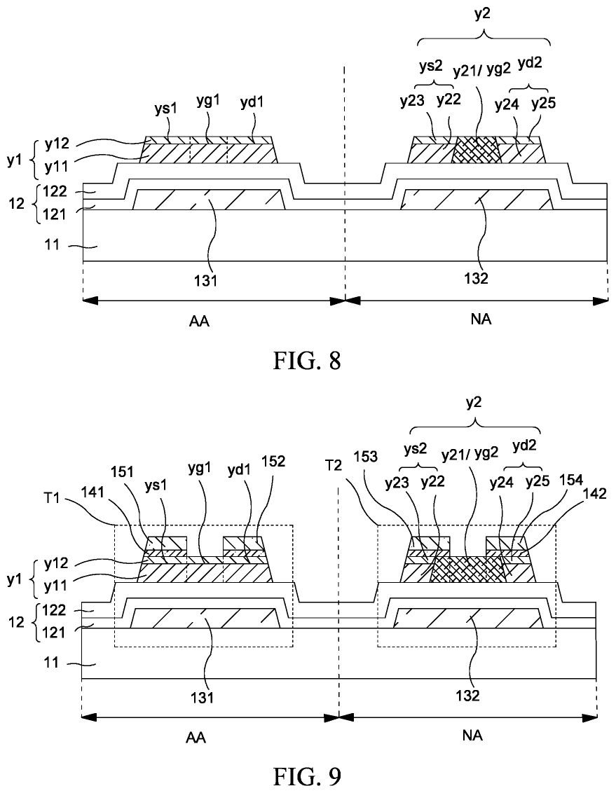

At step B4, further referring to FIG. 8, at least a portion of the second active layer y2 is dehydrogenated and crystallized to form polysilicon by using the BLDA process, in which the second active layer y2 includes a second source contact portion ys2, a second drain contact portion yd2, and a second channel yg2; the second source contact portion ys2 is connected to one side of the second channel yg2, and the second drain contact portion yd2 is connected to the other side of the second channel yg2; the second channel yg2 is polysilicon.

Alternatively, in the second active layer y2, only the second channel yg2 may be the polysilicon layer y21, or the entire second active layer y2 may be the polysilicon layer y21, or alternatively, the polysilicon layer y21 extends from the channel region into the source and drain contact regions.

Here, the second active layer y2 is dehydrogenated by the BLDA process, and then the second active layer y2 is crystallized by the BLDA process. The energy required for the crystallization stage is much greater than the energy required for the dehydrogenation stage.

Since the amorphous silicon material and the microcrystalline silicon material are used as crystallization raw materials, and the microcrystalline silicon material is added, it is possible to reduce the energy required for dehydrogenation and annealing by more than 30% at the same thickness, compared with the crystallization of pure amorphous silicon.

It will be appreciated that in the BLDA process, the energy required for the crystallization of pure amorphous silicon ranges from 350 kw/cm² to 450 kw/cm². The energy required for dehydrogenation ranges from 150 kw/cm² to 250 kw/cm².

In one embodiment, polysilicon may also be formed by using conventional laser processing.

At step B5, further referring to FIG. 9, an ohmic contact material layer and a source-drain metal layer are sequentially formed on one side of both the first active layer y1 and the second active layer y2 which is away from the base 11, and the ohmic contact material layer and the source-drain metal layer are patterned to form first sources 151, first drains 152, a first ohmic contact layer 141, a second ohmic contact layer 142, second sources 153, second drains 154, and the second channels yg2, in which each of the first gates 131, the first active layer y1, the first ohmic contact layer 141, a respective one of the first sources 151 and a respective one of the first drains 152 form a first thin film transistor T1, and each of the second gates 132, the second active layer y2, the second ohmic contact layer 142, a respective one of the second sources 153 and a respective one of the second drains 154 form a second thin film transistor T2; the first source 151 is connected to the first source contact portion ys1 through a portion of the first ohmic contact layer 141, the first drain 152 is connected to the first drain contact portion yd1 through another portion of the first ohmic contact layer 141, the second source 153 is connected to the second source contact portion ys2 through a portion of the second ohmic contact layer 142, and the second drain 154 is connected to the second drain contact portion yd2 through another portion of the second ohmic contact layer 142.

Alternatively, the thicknesses of the first ohmic contact layer 141 and the second ohmic contact layer 142 may be between 15 nm and 40 nm, such as 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, or 40 nm.

The first source 151, the first drain 152, the second source 153 and the second drain 154 may be formed using a metal element selected from the group consisting of chromium, copper, aluminum, gold, silver, zinc, molybdenum, tantalum, titanium, tungsten, manganese, nickel, iron, cobalt, an alloy composed of any of the metal elements described above, an alloy combining any of the metal elements described above, and the like. In addition, the first source 151, the first drain 152, the second source 153 and the second drain 154 may have a single-layer structure or a stacked structure of two or more layers.

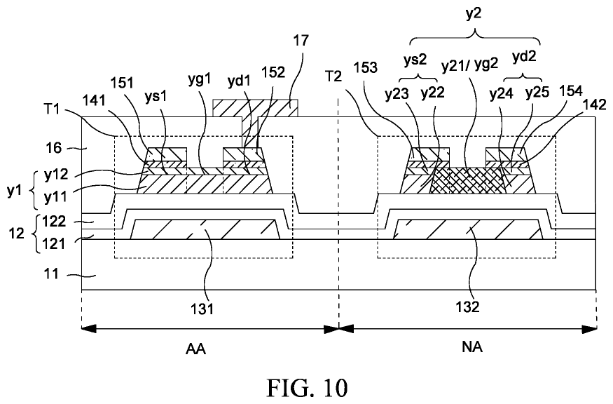

At step B6, further referring to FIG. 10, a protective layer 16 and electrodes 17 are sequentially formed on the first thin film transistors T1 and the second thin film transistors T2.

The protective layer 16 may be formed using a chemical vapor deposition process. The material of the protective layer 16 may be at least one of silicon nitride and silicon oxide. The thickness of the protective layer 16 is between 1500 Angstroms and 4000 Angstroms, for example, 1500 Angstroms, 2000 Angstroms, 2500 Angstroms, 3000 Angstroms, 3500 Angstroms, or 4000 Angstroms.

Alternatively, the protective layer 16 may be etched to form via holes using a yellow light process and a dry etching process.

The material of the electrode 17 includes, but is not limited to, a transparent metal oxide such as Indium tin oxide (ITO). The thickness of the electrode 17 is between 400 Angstroms and 1500 Angstroms, and may be, for example, 400 Angstroms, 500 Angstroms, 600 Angstroms, 700 Angstroms, 800 Angstroms, 900 Angstroms, 1000 Angstroms, 1100 Angstroms, 1200 Angstroms, 1300 Angstroms, 1400 Angstroms, or 1500 Angstroms.

Alternatively, the electrode material layer may be formed by using a physical vapor deposition process, and then a patterned electrode 17 is obtained by a yellow light process and an etching process.

Accordingly, according to embodiments of the present application, it is further provided a display panel including the driving substrate 100 according to any one of the above embodiments.

Alternatively, the display panel may be one of a liquid crystal display panel and an electroluminescent panel.

It should be noted that the structure of the driving substrate in the display panel is similar to or the same as the structure of the driving substrate 100 in the above-described embodiments. Therefore, details are not described herein.

In the driving substrate according to embodiments of the present application, first thin film transistors are provided in a pixel region and second thin film transistors are provided in a frame region, in which a first active layer of the first thin film transistor includes an amorphous silicon layer and a microcrystalline silicon layer stacked, and a channel of the second active layer of the second thin film transistor includes polysilicon, so that mobility of the second thin film transistor is greater than that of the first thin film transistor. Also, since the polysilicon can be formed by crystallizing the amorphous silicon layer and the microcrystalline silicon layer, which are stacked, as a monolithic crystal, the process is simplified, so that the mobility of the second thin film transistor located in the frame region can be improved while the cost is reduced in the present application.

The present application has been described in detail with reference to a driving substrate, a manufacturing method thereof, and a display panel provided in an embodiments of the present application. The principles and the embodiments of the present application are described herein using specific examples. The description of the above embodiments is merely provided to help understand the method and the core idea of the present application. At the same time, variations will occur to those skilled in the art in both the detailed description and the scope of application in accordance with the teachings of the present application. In view of the foregoing, the present description should not be construed as limiting the application.

What is claimed is:

1. A driving substrate comprising a pixel region and a frame region, the frame region being located on at least one side of the pixel region, the driving substrate comprising:
a base;
first thin film transistors disposed on the base and located in the pixel region, wherein each of the first thin film transistors comprises a first active layer, and the first active layer comprises a first amorphous silicon layer and a first microcrystalline silicon layer disposed on a side of the first amorphous silicon layer which is away from the base; and
second thin film transistors disposed on the base and located in the frame region, wherein each of the second thin film transistors comprises a second active layer, the second active layer comprises a second channel comprising polysilicon, and electron mobility of the second thin film transistor is greater than electron mobility of the first thin film transistor.

2. The driving substrate according to claim 1, wherein the first active layer comprises a first source contact portion, a first drain contact portion, and a first channel, the first source contact portion is connected to one side of the first channel, the first drain contact portion is connected to an other side of the first channel, wherein the first source contact portion, the first drain contact portion, and the first channel each comprise the first amorphous silicon layer and the first microcrystalline silicon layer stacked;
the second active layer comprises a second source contact portion and a second drain contact portion, the second source contact portion is connected to one side of the second channel, the second drain contact portion is connected to an other side of the second channel, and the second source contact portion and the second drain contact portion are each made of the polysilicon.

3. The driving substrate according to claim 1, wherein the first active layer further comprises a first source contact portion, a first drain contact portion, and a first channel, the first source contact portion is connected to one side of the first channel, the first drain contact portion is connected to an other side of the first channel, wherein the first source contact portion, the first drain contact portion, and the first channel each comprise the first amorphous silicon layer and the first microcrystalline silicon layer stacked;
the second active layer further comprises a second source contact portion and a second drain contact portion, the second source contact portion is connected to one side of the second channel, the second drain contact portion is connected to an other side of the second channel, the second source contact portion comprises a second amorphous silicon layer and a second microcrystalline silicon layer, the second microcrystalline silicon layer is disposed on a side of the second amorphous silicon layer which is away from the base, the second drain contact portion comprises a third amorphous silicon layer and a third microcrystalline silicon layer, and the third microcrystalline silicon layer is disposed on a side of the third amorphous silicon layer which is away from the base.

4. The driving substrate according to claim 1, wherein the polysilicon is formed by crystallizing a fourth amorphous silicon layer and a fourth microcrystalline silicon layer, which are stacked, as a monolithic crystal, the fourth amorphous silicon layer is provided in a same layer as the first amorphous silicon layer, and the fourth microcrystalline silicon layer is provided in a same layer as the first microcrystalline silicon layer.

5. The driving substrate according to claim 2, wherein the polysilicon is formed by crystallizing a fourth amorphous silicon layer and a fourth microcrystalline silicon layer, which are stacked, as a monolithic crystal, the fourth amorphous silicon layer is provided in a same layer as the first amorphous silicon layer, and the fourth microcrystalline silicon layer is provided in a same layer as the first microcrystalline silicon layer.

6. The driving substrate according to claim 3, wherein the polysilicon is formed by crystallizing a fourth amorphous silicon layer and a fourth microcrystalline silicon layer, which are stacked, as a monolithic crystal, the fourth amorphous silicon layer is provided in a same layer as the first amorphous silicon layer, and the fourth microcrystalline silicon layer is provided in a same layer as the first microcrystalline silicon layer.

7. The driving substrate according to claim 1, wherein the polysilicon has a grain width greater than 2 microns.

8. The driving substrate according to claim 7, wherein the polysilicon has a grain width greater than 6 microns.

9. The driving substrate according to claim 1, wherein a thickness of the first microcrystalline silicon layer is between 10% and 30% of a thickness of the first active layer.

10. The driving substrate according to claim 2, wherein the driving substrate further comprises a gate insulating layer, the first thin film transistor comprises a first gate, the second thin film transistor comprises a second gate, the first gate and the second gate are both disposed on the base, the gate insulating layer covers the first gate and the second gate, the first active layer is disposed on a side of the gate insulating layer which is away from the base, and the second active layer is disposed on a side of the gate insulating layer which is away from the base;
in an orthographic projection pattern of the driving substrate, the first active layer and the first gate are overlapped, and the second active layer and the second gate are overlapped;
the gate insulating layer comprises a silicon oxide layer and a silicon nitride layer, the silicon nitride layer is disposed on a side of the silicon oxide layer which is away from the base.

11. The driving substrate according to claim 10, wherein a thickness of the silicon nitride layer is greater than a thickness of the silicon oxide layer.

12. The driving substrate according to claim 10, wherein a thickness of the silicon oxide layer is less than or equal to 250 nm, and a thickness of the silicon nitride layer is between 200 nm and 400 nm.

13. The driving substrate according to claim 10, wherein the first thin film transistor further comprises a first ohmic contact layer, a first source and a first drain, and the second thin film transistor further comprises a second ohmic contact layer, a second source and a second drain;
a portion of the first ohmic contact layer is provided on the first source contact portion, an other portion of the first ohmic contact layer is provided on the first drain contact portion, the first source is connected to the first source contact portion through the portion of the first ohmic contact layer, and the first drain is connected to the first drain contact portion through the other portion of the first ohmic contact layer;
a portion of the second ohmic contact layer is provided on the second source contact portion, an other portion of the second ohmic contact layer is provided on the second drain contact portion, the second source is connected to the second source contact portion through the portion of the second ohmic contact layer, and the second drain is connected to the second drain contact portion through the other portion of the second ohmic contact layer.

14. The driving substrate according to claim 1, wherein the driving substrate comprises a demultiplexing circuitry, the demultiplexing circuitry comprises ones of the second thin film transistors, a gate of each of the ones of the second thin film transistors is connected to a corresponding one of signal control terminals, first electrodes of the ones of the second thin film transistors are connected to a data signal input terminal, and a second electrode of each of the ones of the second thin film transistors is connected to a corresponding one of data lines.

15. The driving substrate according to claim 2, wherein the driving substrate comprises a demultiplexing circuitry, the demultiplexing circuitry comprises ones of the second thin film transistors, a gate of each of the ones of the second thin film transistors is connected to a corresponding one of signal control terminals, first electrodes of the ones of the second thin film transistors are connected to a data signal input terminal, and a second electrode of each of the ones of the second thin film transistors is connected to a corresponding one of data lines.

16. The driving substrate according to claim 3, wherein the driving substrate comprises a demultiplexing circuitry, the demultiplexing circuitry comprises ones of the second thin film transistors, a gate of each of the ones of the second thin film transistors is connected to a corresponding one of signal control terminals, first electrodes of the ones of the second thin film transistors are connected to a data signal input terminal, and a second electrode of each of the ones of the second thin film transistors is connected to a corresponding one of data lines.

17. A display panel comprising a driving substrate comprising a pixel region and a frame region, the frame region being located on at least one side of the pixel region, the driving substrate comprising:
a base;
first thin film transistors disposed on the base and located in the pixel region, wherein each of the first thin film transistors comprises a first active layer, and the first active layer comprises a first amorphous silicon layer and a first microcrystalline silicon layer disposed on a side of the first amorphous silicon layer which is away from the base; and
second thin film transistors disposed on the base and located in the frame region, wherein each of the second thin film transistors comprises a second active layer, the second active layer comprises a second channel comprising polysilicon, and electron mobility of the second thin film transistor is greater than electron mobility of the first thin film transistor.

18. The display panel according to claim 17, wherein the first active layer comprises a first source contact portion, a first drain contact portion, and a first channel, the first source contact portion is connected to one side of the first channel, the first drain contact portion is connected to an other side of the first channel, wherein the first source contact portion, the first drain contact portion, and the first channel each comprise the first amorphous silicon layer and the first microcrystalline silicon layer stacked;
the second active layer comprises a second source contact portion and a second drain contact portion, the second source contact portion is connected to one side of the second channel, the second drain contact portion is connected to an other side of the second channel, and the second source contact portion and the second drain contact portion are each made of the polysilicon.

19. The display panel according to claim 17, wherein the first active layer further comprises a first source contact portion, a first drain contact portion, and a first channel, the first source contact portion is connected to one side of the first channel, the first drain contact portion is connected to an other side of the first channel, wherein the first source contact portion, the first drain contact portion, and the first channel each comprise the first amorphous silicon layer and the first microcrystalline silicon layer stacked;
the second active layer further comprises a second source contact portion and a second drain contact portion, the second source contact portion is connected to one side of the second channel, the second drain contact portion is connected to an other side of the second channel, the second source contact portion comprises a second amorphous silicon layer and a second microcrystalline silicon layer, the second microcrystalline silicon layer is disposed on a side of the second amorphous silicon layer which is away from the base, the second drain contact portion comprises a third amorphous silicon layer and a third microcrystalline silicon layer, and the third microcrystalline silicon layer is disposed on a side of the third amorphous silicon layer which is away from the base.

20. A manufacturing method of a driving substrate, comprising:
forming first gates and second gates on a base, wherein each of the first gates is located in a pixel region and each of the second gates is located in a frame region;
forming a gate insulating layer on the base, wherein the gate insulating layer covers the first gates and the second gates;
sequentially forming an amorphous silicon material layer and a microcrystalline silicon material layer on the gate insulating layer, patterning the amorphous silicon material layer and the microcrystalline silicon material layer to form a first active layer located in the pixel region and a second active layer located in the frame region, wherein the first active layer comprises a first source contact portion, a first drain contact portion, and a first channel, the first source contact portion is connected to one side of the first channel, the first drain contact portion is connected to an other side of the first channel, and the first source contact portion, the first drain contact portion, and the first channel each comprises a first amorphous silicon layer and a first microcrystalline silicon layer stacked;
dehydrogenating and crystallizing at least a portion of the second active layer to form polysilicon, wherein the second active layer comprises a second source contact portion, a second drain contact portion, and a second channel, the second source contact portion is connected to one side of the second channel, the second drain contact portion is connected to an other side of the second channel, and the second channel are made of the polysilicon;
sequentially forming an ohmic contact material layer and a source-drain metal layer on one side of both the first active layer and the second active layer which is away from the base, and patterning the ohmic contact material layer and the source-drain metal layer to form first sources, first drains, a first ohmic contact layer, a second ohmic contact layer, second sources and second drains, wherein each of the first gates, the first active layer, the first ohmic contact layer, a respective one of the first sources and a respective one of the first drains form a first thin film transistor, and each of the second gates, the second active layer, the second ohmic contact layer, a respective one of the second sources and a respective one of the second drains form a second thin film transistor; the first source is connected to the first source contact portion through a portion of the first ohmic contact layer, the first drain is connected to the first drain contact portion through an other portion of the first ohmic contact layer, the second source is connected to the second source contact portion through a portion of the second ohmic contact layer, and the second drain is connected to the second drain contact portion through an other portion of the second ohmic contact layer.
